(19) United States
(12) Patent Application Publication
(10) Pub. No.: US 2009/0057869 A1
(43) Pub. Date: Mar. 5, 2009

(54) CO-PACKAGED HIGH-SIDE AND LOW-SIDE NMOSFETS FOR EFFICIENT DC-DC POWER CONVERSION

(75) Inventors: Francois Hebert, San Mateo, CA (US); Xiaotian Zhang, San Jose, CA (US); Kai Liu, Mountain View, CA (US); Ming Sun, Sunnyvale, CA (US); Anup Bhalla, Santa Clara, CA (US)

Correspondence Address: JOSHUA D. ISENBERG;JDI PATENT, 809 CORPORATE WAY, FREMONT, CA, 94539, US

(73) Assignee: ALPHA & OMEGA SEMICONDUCTOR, LTD., Hamilton (BM)

(21) Appl. No.: 11/849,160

(22) Filed: Aug. 31, 2007

(51) Int. Cl. H01L 23/52

(52) U.S. Cl. 257/691; 257/E23.141

(57) ABSTRACT

A circuit package assembly is disclosed. The assembly includes a conductive substrate; a high-side n-channel metal oxide semiconductor field effect transistor (NMOSFET) having a source on a side facing a surface of the conductive substrate and in electrical contact therewith and a low-side standard n-channel metal oxide semiconductor field effect transistor (NMOSFET) having a drain on a side facing the conductive substrate and in electrical contact therewith. Co-packaging of high-side and low-side NMOSFETs in this manner may reduce package size and parasitic inductance and capacitance compared to conventional packaging.

### FIELD OF THE INVENTION

This invention generally relates to semiconductor devices and more particularly to co-packaged high-side and low-side metal oxide semiconductor field effect transistors (MOSFETs) for efficient DC-DC power conversion.

### BACKGROUND OF THE INVENTION

Conventional technologies to further reduce the size of power devices, improve efficiency of power devices, and reduce cost and number of packages in DC-DC power conversion circuits are challenged by several technical difficulties and limitations. In the field of MOSFET power devices there are known transistors with N-channels (NMOSFET) which can be driven in conduction by means of a positive gate voltage in relation to a source voltage. In addition there are MOSFETs with P-channels (PMOSFET) which can be driven in conduction by means of negative gate voltage in relation to the source voltage.

Conventional power converters using NMOSFET power devices typically require a minimum of three components: a gate driver IC, a high-side NMOSFET and a low-side NMOSFET. Conventionally, the high-side and low-side NMOSFETs are implemented using two separate discrete packages, or built on two separate die pads within one package, which requires more space in the package. The use of two separate die pads also results in more parasitic inductances and/or capacitances and increases thermal resistance due to smaller die pads. The die pad refers to the exposed metal area where the MOSFET is die attached to. In addition, the trend toward miniaturization in many devices that use power converters tends to reduce the available die pad area resulting in a reduced high-side and/or low-side chip area, which increases the drain to source on state resistance R_{ds-on}.

FIG. 1 is a top view of a package including high-side and low-side NMOSFETs for a power converter of the prior art. As shown in FIG. 1, a high-side standard vertical double diffused metal oxide semiconductor field effect transistor (VDMOSFET) 102 has a drain connected to a drain pad (not shown) on a bottom side facing a conductive first die pad 106. The drain pad may be may be connected to the first die pad 106 by a conductive epoxy layer 118. A second low-side standard VDMOSFET 104 is used as a low-side NMOSFET. As used herein, a VDMOSFET refers to an n-channel VDMOSFET, unless expressly stated otherwise. As used herein, a standard VDMOSFET refers to a bottom drain VDMOSFET, i.e., one in which the source is formed at the top of the die and the drain is formed from the substrate, unless expressly stated otherwise. Conventional VDMOSFET devices are bottom drain. The low-side standard VDMOSFET 104 has a drain electrically and physically connected to the die pad 108 through a bottom side drain pad (not shown), e.g., by a conductive epoxy layer 120 or other die attach means such as solder or eutectic die attach. A source pad 107 on a top side of the high-side standard VDMOSFET 102 facing away from the first die pad 106 is electrically connected to source leads 110 through bond wires 114. Similarly, a top-side source pad 109 of the low-side standard VDMOSFET 104 is electrically connected to the source leads 112 through bond wires 116. Electrical connection to gates of the high-side NMOSFET 102 and low-side NMOSFET 104 may be made through gate pads 103, 105 located on sides of the NMOSFETs 102, 104 facing away from the die pads 106, 108. In power converter package, the high-side source and the low-side drain are typically connected to each other. In conventional packaging this may be accomplished with additional bond wires 122 between the second die pad 108 and the source pad 107 of the high-side VDMOSFET 102. The additional bond wires 122 add parasitic inductance, which hinders operation at high frequency. The package includes a molding compound that encases all the parts. The boundary of the package is indicated by the dashed line 101.

To electrically isolate the first and second die pads 106, 108 they must be mounted to an electrically insulating material and spaced apart from each other by a gap of width d. The gap width d between the two isolated die pads 106 and 108 results in a reduced available die placement area. To fit the NMOSFETs within the smaller area, smaller high-side and/or low-side NMOSFET is used. This results in a reduced high-side and/or low-side chip area, which tends to increase the drain to source resistance R_{ds-on}. The reduced die pad area also increases the thermal resistance.

A high-side and a low-side MOSFET can be put on the same die pad if one was an NMOSFET and the other was a PMOSFET. However the performance of the P-channel MOSFET (PMOSFET) is much less than that of an N-Channel MOSFET (NMOSFET) because of the much lower mobility of holes in PMOSFETs. This is well-known to individuals skilled in the art.

It is within this context that embodiments of the present invention arise.

### BRIEF DESCRIPTION OF THE DRAWINGS

Objects and advantages of the invention will become apparent upon reading the following detailed description and upon reference to the accompanying drawings in which:

FIG. 1 is a top view of a high-side and low-side NMOSFETs package assembly for a power converter of the prior art.

FIGS. 2A-2B are top views of circuit package assemblies having high-side and low-side NMOSFETs according to an embodiment of the present invention.

FIG. 2C is a three-dimensional view of the circuit package assembly of FIG. 2B.

FIG. 2D is a circuit diagram of a power converter circuit that may be used in conjunction with the high-side and low-side NMOSFET circuit package assemblies of FIGS. 2A-2C.

FIG. 2E is a side view cross-sectional schematic diagram of a high-side and low-side NMOSFET circuit package assembly of the prior art.

FIG. 2F is a side view cross-sectional schematic diagram of a high-side and low-side NMOSFET circuit package assembly according to an embodiment of the present invention.

FIG. 2G is an equivalent circuit diagram of a high-side and low-side NMOSFET circuit package of the prior art.

FIG. 2H is an equivalent circuit diagram of a high-side and low-side NMOSFET circuit package assembly according to an embodiment of the present invention.

FIG. 3 is a top view of a plate bonded circuit package with co-packaged high-side and low-side NMOSFETs package having a high-side bottom source lateral double diffused MOSFET (LDMOSFET), with wire bonded gates according to an embodiment of the present invention.

FIG. 4 is a top view of a circuit package assembly having co-packaged high-side and low-side NMOSFETs packaged using plate bonded gates according to an embodiment of the present invention.

FIG. 5A is a top view of a circuit package assembly having plate bonded co-packaged high-side and low-side NMOSFETs package with the high-side NMOSFET packaged in a flip chip configuration according to an embodiment of the present invention.

FIG. 5B is a cross-sectional view along line B-B of FIG. 5A.

FIG. 5C is a cross-sectional view along line C-C of FIG. 5A.

FIG. 6 is a top view of a circuit package assembly having co-packaged high-side and low-side NMOSFETs packaged with aluminum power ribbon interconnections according to an embodiment of the present invention.

FIG. 7 is a top view of a circuit package assembly having co-packaged high-side and low-side NMOSFETs package with a high-side bottom source or flip chip vertical MOSFET with an aluminum power ribbon interconnections according to an embodiment of the present invention.

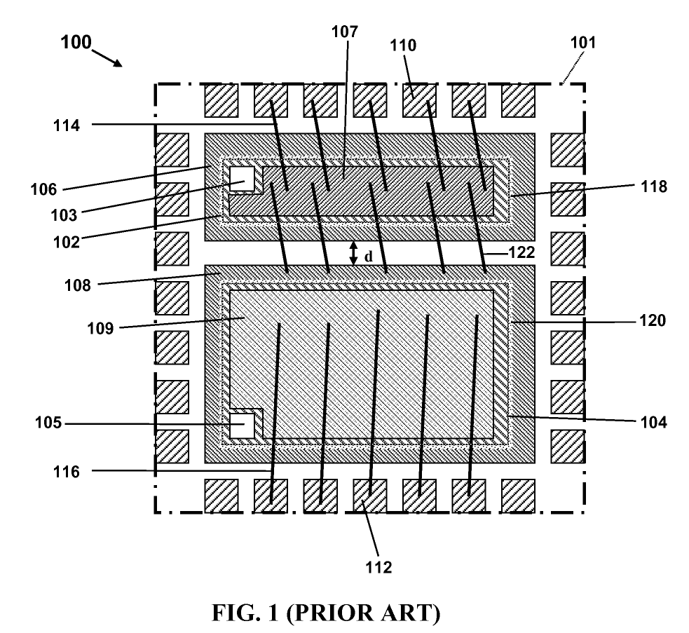

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the examples of embodiments of the invention described below are set forth without any loss of generality to, and without imposing limitations upon, the claimed invention.

As discussed above, power converters that use NMOSFET power devices typically have three components: a gate driver IC, a high-side NMOSFET and a low-side NMOSFET. Conventionally, the high-side and low-side NMOSFETs are built on two separate die pads within one package. One possible approach to reducing the number of components is to use a combination of PMOSFET and NMOSFET power devices. If, e.g., the high-side power device is a PMOSFET device and the low-side power device is an NMOSFET device, both power devices may be attached to the same die pad. Unfortunately, the performance of PMOSFET devices tends to be much less than that of the NMOSFET devices. As a result a power converter circuit that uses PMOSFET and NMOSFET devices tends to have a higher DC resistance and a lower efficiency. However, conventional mounting of low-side and high-side bottom drain NMOSFET devices leads to undesirable parasitic inductances due, e.g., to bond wires used connect the source of the high-side NMOSFET to the drain of the low-side NMOSFET. Conventional NMOSFETs are made with the source on the top and the drain on the bottom side. For circuits like high-side low-side power converter, this setup requires mounting the NMOSFETs on two separate die pads, which increases thermal resistance and allows less space for the chips.

Embodiments of the present invention overcome the disadvantages of low efficiency and high resistance associated with the use of PMOSFET and NMOSFET power devices mounted to a common substrate in a voltage converter circuit package by using NMOSFET devices for the high-side and low-side NMOSFETs. Embodiments of the present invention overcome the problems of parasitic inductances associated with conventionally mounting bottom drain high-side and low-side NMOSFET devices to separate die pads by conventionally mounting a bottom drain low-side NMOSFET device to a die pad and mounting a high-side NMOSFET device to the same die pad with its source facing the same die pad. Embodiments of the present invention overcome the problems of increased thermal resistance and smaller areas for NMOSFET chips associated with conventionally mounting the high-side and low-side chips on separate die pads by mounting a bottom drain low-side NMOSFET device to a die pad and mounting a high-side NMOSFET device to the same die pad with its source facing the same die pad.

In embodiments of the present invention, the high-side and low-side NMOSFETs may be combined on one conductive substrate or die pad. The high-side and low-side NMOSFETs are packaged together with a source side of the high-side NMOSFET and a drain side of the low-side NMOSFET facing a surface of the common substrate. A power converter circuit package according to an embodiment of the present invention may include a bottom source NMOSFET positioned at a high-side of a common die pad and a standard VDMOSFET having a bottom drain positioned at a low-side of the common die pad.

As used herein, a VDMOSFET refers to an n-channel VDMOSFET, unless expressly stated otherwise. Furthermore, as used herein, a standard VDMOSFET refers to a bottom drain VDMOSFET, i.e., the drain formed from the substrate, unless expressly stated otherwise.

By way of example, the low-side standard VDMOSFET may be a shielded gate trench (SGT) double-diffused metal oxide semiconductor (DMOS) as disclosed in U.S. Pat. No. 5,998,833 which is incorporated herein by reference, a standard vertical trench-gate DMOS such as part No. A04922 available from Alpha & Omega Semiconductor (AOS) of Sunnyvale, Calif., a standard vertical planar MOSFET as disclosed in U.S. Pat. No. 4,344,081, which is incorporated herein by reference, or a planar split gate vertical MOSFET as described in pending U.S. patent application Ser. No. 11/444,853, entitled “Planar Split-Gate High-Performance MOSFET Structure and Manufacturing Method” filed on May 31, 2006, which is incorporated herein by reference. A trench DMOS may yield low specific resistance (R_{ds-on}*Area) for best performance. Low capacitance may be achieved by using shielded gate trench DMOS technology.

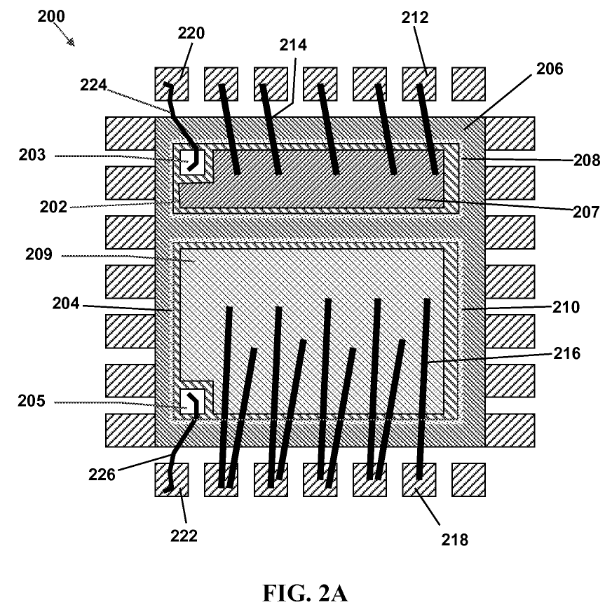

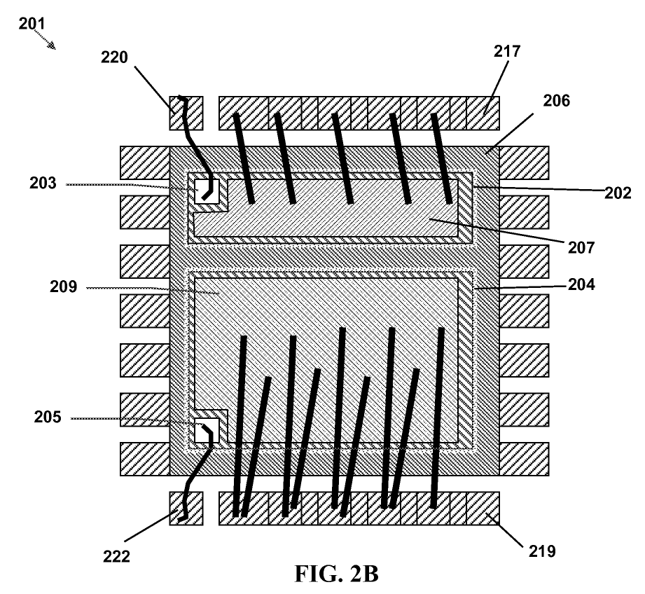

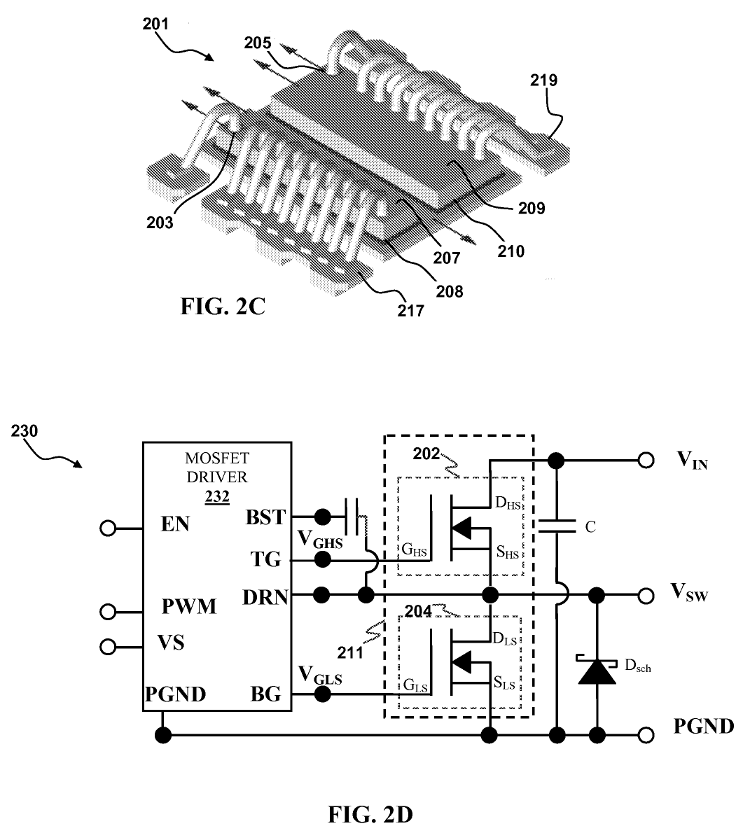

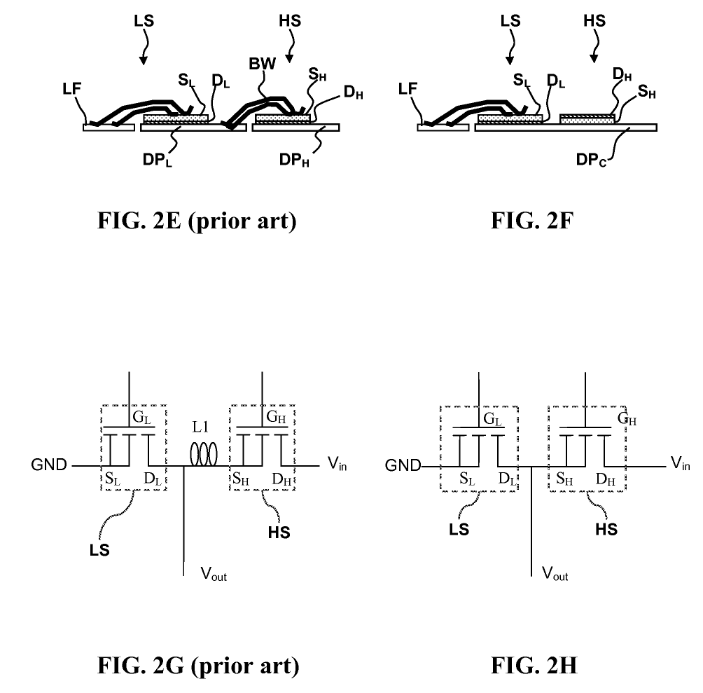

According to an embodiment, the high-side bottom source NMOSFET may be a lateral double diffused MOSFET (LDMOSFET), which may be a bottom source LDMOSFET as described in pending U.S. patent application Ser. No. 11/495,803, entitled “Bottom Source LDMOSFET Structure and Method” filed on Jul. 27, 2006, the entire disclosure of which are incorporated herein by reference. The bottom source LDMOSFET has a drain located on the top side, and a source—formed from the substrate—on the bottom, FIGS. 2A-2B are top views of high-side and low-side NMOSFET circuit package assemblies according to an embodiment of the present invention. Power converter circuit assemblies of the types shown in FIGS. 2A-2B as well as others shown and described elsewhere in this application may be used in many different applications that use high-side and low-side devices. Examples of such applications include, but are not limited to power converter circuits, audio amplification circuits, radio frequency (RF) amplification circuits and operational amplifier (op-amp) output stages. By way of example, and without limitation, circuit package assemblies of the types shown in FIGS. 2A-2B may be used in power converter circuits.

As shown in FIG. 2A, in a package assembly 200 a bottom source n-channel LDMOSFET 202 may be positioned at a high-side and a low-side standard n-channel VDMOSFET 204 may be positioned at a low-side of a common die pad 206. As used herein, high-side LDMOSFET refers to high-side n-channel bottom source LDMOSFET, i.e. with a drain formed on the top of the die and the source—formed from the substrate of the die—on the bottom of the die, unless expressly stated otherwise. The high-side LDMOSFET 202 may be mounted to the common die pad 206 with its source facing and physically attached to and electrically connected to the common die pad 206 e.g., by a conductive adhesive layer 208 such as a conductive epoxy or, more preferably, solder. The low-side standard VDMOSFET 204 may similarly be physically attached and electrically connected to the common die pad 206 by a conductive adhesive layer 210 such as a conductive epoxy or, more preferably, solder, with a drain of the low-side standard VDMOSFET 204 facing the common die pad 206. Gate pads 203, 205 on the sides of the high-side LDMOSFET 202 and low-side standard VDMOSFET 204 not facing the common die pad 206 may be electrically connected to the gate leads 220 and 222 through bond wires 224 and 226 respectively. A drain pad 207 of the high-side LDMOSFET 202 on a side not facing the common die pad 206 may be electrically connected to individual drain leads 212 through bond wires 214. Similarly, a source pad 209 of the low-side standard VDMOSFET 204 may be individually electrically connected to individual source leads 218 through bond wires 216. As used herein the terms “gate pad”, “drain pad” and “source pad” refer to relatively exposed and electrically conductive areas of a MOSFET that are in electrical contact with the MOSFET's gate, source and drain regions respectively. In these figures and in the figures to follow, the package is encased in a molding compound which is not shown, unless expressly stated otherwise.

FIGS. 2B-2C depict co-packaging of high-side and low-side NMOSFETs in a power converter circuit package assembly 201 that is similar to the one described in FIG. 2A except the top drain pad 207 of the high-side LDMOSFET 202 and top source pad 209 of the low-side standard VDMOSFET 204 are electrically connected to common drain lead 217 and common source lead 219 respectively.

FIG. 2D is a circuit diagram of a power converter circuit 230 that may incorporate high-side and low-side MOSFETs mounted to a common substrate, as shown e.g., in FIGS. 2A-2C. As shown in FIG. 2D, the drain D_{HS} of the high-side LDMOSFET 202 is electrically coupled to an input voltage V_{IN}, the source S_{HS} of the high-side LDMOSFET 202 is electrically coupled to the drain D_{LS} of the low-side standard VDMOSFET 204. The source S_{LS} of the low-side standard VDMOSFET 204 is electrically coupled to a ground pin PGND. Gates (G_{HS} and G_{LS}) of the high-side LDMOSFET 202 and low-side standard VDMOSFET 204 are electrically coupled to high-side gate voltage V_{GHS} and low-side gate voltage V_{GLS}. The high-side and low-side MOSFETs 202, 204 are encased in molding compound as indicated by the dashed line boundary 211. The gate voltages V_{GHS}, V_{GLS} may be supplied by a MOSFET driver integrated circuit (IC) 232 of a type commonly used for power conversion circuits. Examples of commercially available MOSFET driver integrated circuits that may be used as the MOSFET driver IC 232 include, but are not limited to, a model ISL6207 High Voltage Synchronous Rectified Buck MOSFET Driver from Intersil Corporation of Milpitas, Calif. or a model SC1205 High-Speed Synchronous Power MOSFET Driver from Semtech Corporation of Camarillo, Calif.

By way of example and without loss of generality, the MOSFET driver IC 232 may have inputs including an enable input EN, a pulse width modulation input PWM, a positive supply voltage VS a ground pin PGND and a drain pin DRN. In addition, the MOSFET driver IC 232 may include output pins such as a high-side gate driver TG a low side gate driver BG and a bootstrap voltage pin BST. A suitable source voltage (e.g., +5 V) may be applied to the supply voltage pin VS. In some embodiments, a capacitor may be coupled between the voltage source and the ground pin PGND. The MOSFET driver may be configured such that when a voltage sufficient voltage is applied to the enable pin EN the internal circuitry of the MOSFET driver 232 is enabled. A pulse width modulation signal applied to the pulse width modulation input PWM may provide a driving signal for the MOSFET driver IC 232.

The high-side gate driver TG may be coupled to the gate GHS of the high-side MOSFET 202 to provide the high-side gate voltage V_{GHS}. Similarly, the low side gate driver BG may be coupled to the gate G_{LS} of the low-side MOSFET 204 to provide the low-side gate voltage V_{GLS}. The drain pin DRN may be connected between the source S_{HS} of the high-side MOSFET 202 and the drain D_{LS} of the low-side MOSFET 204 to provide a return path for the high-side gate driver TG. The bootstrap voltage pin BST may provide a floating bootstrap voltage for the high-side gate MOSFET 202. In some implementations, a bootstrap capacitor CB may be coupled between the bootstrap voltage pin BST and the drain pin DRN.

A capacitor C may be electrically coupled between V_{IN} and an output voltage V_{SW} (switching voltage), and a Schottky diode D_{Sch} is electrically coupled between the switching voltage V_{SW} and the ground pin PGND, which may be connected to the source ground SGND. The integrated Schottky is to improve the circuit performance through reduced low-side body diode recovery losses, reducing ringing during switching, etc. Note that the Schottky diode may be integrated in the low-side MOSFET device 204. Examples of suitable MOSFETs co-packaged with Schottky dioees include, but are not limited to the SRFET™ family of products, such as the part No. AOL1412 available from Alpha & Omega Semiconductor (AOS) of Sunnyvale, Calif.

The cross-sectional diagrams of FIG. 2E and FIG. 2F and the respectively corresponding equivalent circuit schematics of FIGS. 2G and 2H illustrate an advantage of co-packaging a high-side NMOSFET HS and a low-side NMOSFET LS. In FIG. 2E, the high-side NMOSFET HS and the low-side NMOSFET LS are both bottom drain NMOSFETS positioned on two electrically isolated die pads DP_{H}, DP_{L} as in the prior art. A drain DL of the low-side MOSFET faces the low-side die pad DP_{L}. A drain DH of the high-side MOSFET faces the high-side die pad DP_{H}. Though not shown in the drawing, the high-side and low-side NMOSFETs HS, LS, and the die pads DP_{H}, DP_{L}, and the leadframe LF may be encased in molding compound. A source SL of the low-side NMOSFET may be electrically coupled to a lead frame LF. A drain DL of the low-side NMOSFET is coupled to the source S_{H} of the high-side NMOSFET by bond wires BW in electrical contact with the low-side die pad DP_{L}. As shown in FIG. 2G a parasitic inductance L1 is present due to bond wires BW. By contrast, co-packaging of the high-side NMOSFET HS and the low-side MOSFET LS on a common die pad DP_{C} with the source S_{H} of the high-side NMOSFET facing the common die pad DP_{C} as in FIG. 2F and one may eliminate the bond wires BW and associated parasitic inductance L1 as seen in FIG. 2H. Though not shown in the drawing, the high-side and low-side NMOSFETs HS, LS, and the common die pad DP_{C}, and the leadframe LF are encased in molding compound. It is noted that in FIG. 2G and FIG. 2H parasitic capacitances and inductances due to external connections have been ignored for the sake of simplicity.

In some embodiments, use of a planar MOSFET results in ultra-low junction capacitance. In theory, either the high-side MOSFET or the low-side MOSFET or both may be planar. In a preferred embodiment, the high-side MOSFET may be a planar device, combined with a low-side MOSFET having a Shielded Gate Trench DMOS style structure, e.g., of the type shown in U.S. Pat. No. 5,998,833, most likely with an integrated Schottky diode, for the low-side MOSFET LS.

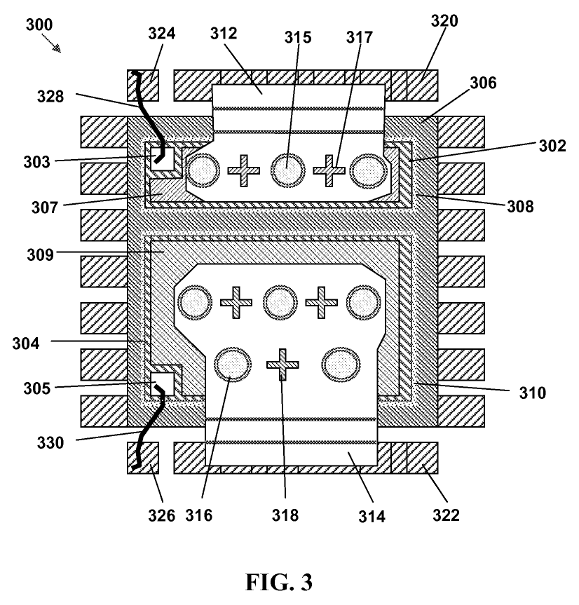

FIG. 3 is a top view of a plate bonded power converter circuit package 300 having co-packaged high-side and low-side NMOSFETs including a high-side bottom source LDMOSFET and wire bonded gates according to an embodiment of the present invention. As shown in FIG. 3, a high-side LDMOSFET 302 and a low-side standard (bottom drain) VDMOSFET 304 may be co-packaged in a common die pad 306. The high-side LDMOSFET 302 and the low-side standard VDMOSFET 304 are electrically attached to the common die pad 306 by conductive layers 308 and 310 respectively. The conductive layers 308, 310 may be layers of conductive adhesive, e.g., conductive epoxy, or more preferably, solder. A source pad of the high-side LDMOSFET 302 and a drain pad of the low-side standard VDMOSFET 304, which are found on the bottoms of their respective dies, may be located facing the common die pad 306. Gate pads 303, 305 of the high-side LDMOSFET 302 and low-side standard VDMOSFET 304 respectively may be electrically connected to gate leads 324 and 326 through bond wires 328 and 330 respectively.

A drain pad 307 on a side of the high-side LDMOSFET 302 facing away from the die pad 306 may be electrically connected to a drain lead 320 through a first bond plate 312. Similarly, a source pad 309 on a side of the low-side standard VDMOSFET 304 facing away from the die pad 306 may be electrically connected to a source lead 322 through a second bond plate 314. The first bond plate 312 includes a plurality of drain dimples 315 and anchor holes 317. The second bond plate 314 includes a plurality of source dimples 316 and anchor holes 318. The drain dimples 315 may be positioned and stamped or punched on the first bond plate 312 so as to align with the drain pad 307 of the high-side LDMOSFET 302 during solder reflow. Similarly, the source dimples 316 may be positioned and stamped or punched on the second bond plate 314 so as to align with the source pad 309 of the low-side standard VDMOSFET 304 during the solder reflow. Soft solder may be disposed in the drain dimples 315 and source dimples 316 and allowed to flow through holes (not shown) in the dimples 315, 316 to the drain pad 307 on the high-side LDMOSFET 302 and to the source pad 309 on the low-side standard VDMOSFET 304 respectively to form electrical interconnections between the drain of the high-side LDMOSFET 302 and the drain lead 320 and between the sources of the low-side standard VDMOSFET 304 and the source lead 322.

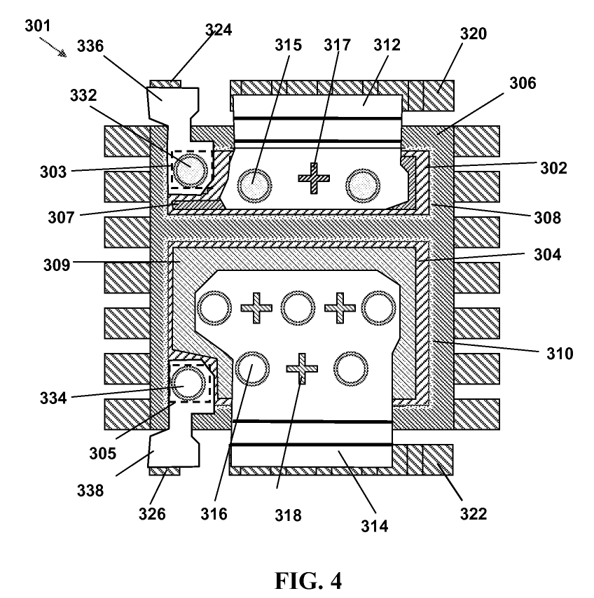

FIG. 4 is a top view of a plate bonded power converter circuit package 301 having co-packaged high-side and low-side NMOSFETs including a high-side LDMOSFET and plate bonded gates according to an embodiment of the present invention. The plate bonded co-packaged high-side and low-side NMOSFET assembly of FIG. 4 is similar to one in FIG. 3, except gate pads 303, 305 of the bottom source LDMOSFET 302 and low-side standard VDMOSFET 304 respectively are electrically connected to gate leads 324 and 326 through gate bond plates 336 and 338 respectively. The high-side gate plate 336 includes a dimple 332, which is positioned and stamped or punched on the high-side gate bond plate 336 so as to align with the gate pad 303 of the high-side bottom source LDMOSFET 302 during solder reflow. The low-side gate bond plate 338 includes a dimple 334, which is positioned and stamped or punched on the low-side gate bond plate 338 so as to align with the gate pad 305 of the low-side standard VDMOSFET 304 during solder reflow. Electrical interconnections between the gate pad 303 of the high-side LDMOSFET 302 and the gate bond plate 336 and between the gate pad 305 of the low-side standard VDMOSFET 304 and the gate bond plate 338 may be formed by disposing soft solder all over the exposed openings on the gate pads 303, 305 and squeezed around the gate dimples 332 and 334 to reduce resistance and stress.

Additional details regarding interconnections using bond plates having dimples as described above with respect to FIG. 3 and FIG. 4 may be found in a pending U.S. patent application Ser. No. 11/799,467 entitled “Semiconductor Package Having Dimpled Plate Interconnection” filed on Apr. 30, 2007, to Ming Sun (Attorney Docket No. AOS025), the entire disclosure of which is incorporated herein by reference.

The preceding embodiments of the invention utilized a bottom source NMOSFET as the high-side NMOSFET. As used herein the term “bottom source” MOSFET refers to a MOSFET that has been manufactured with the source region and/or its associated source pad being fabricated at the bottom of the chip and the other regions (gate and drain) and/or their associated pads being fabricated on top of the source region and/or source pad. An example of a bottom source MOSFET is described in pending U.S. patent application Ser. No. 11/495,803, which has been incorporated herein by reference. In a “standard” (or bottom drain) MOSFET, by contrast, the drain region and/or its associated drain pad is fabricated at the bottom of the chip and the other regions (source and gate) and/or or their associated pads are fabricated on top of the drain region and/or drain pad. According to an embodiment of the present invention, the high-side MOSFET may be a standard (bottom drain) VDMOSFET mounted to the common die pad in a “flipped” configuration with a bottom drain pad on a side facing away from the common die pad and a source pad located on an opposite side of the VDMOSFET facing the common die pad. The high-side VDMOSFET in such embodiments may be a planar split gate vertical MOSFET, shield gate trench vertical (SGT) MOSFET, standard trench VDMOSFET or standard trench DMOS.

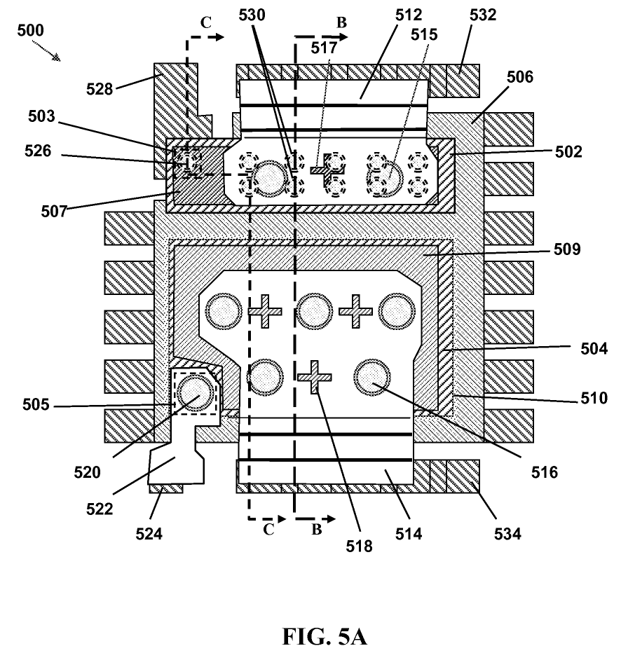

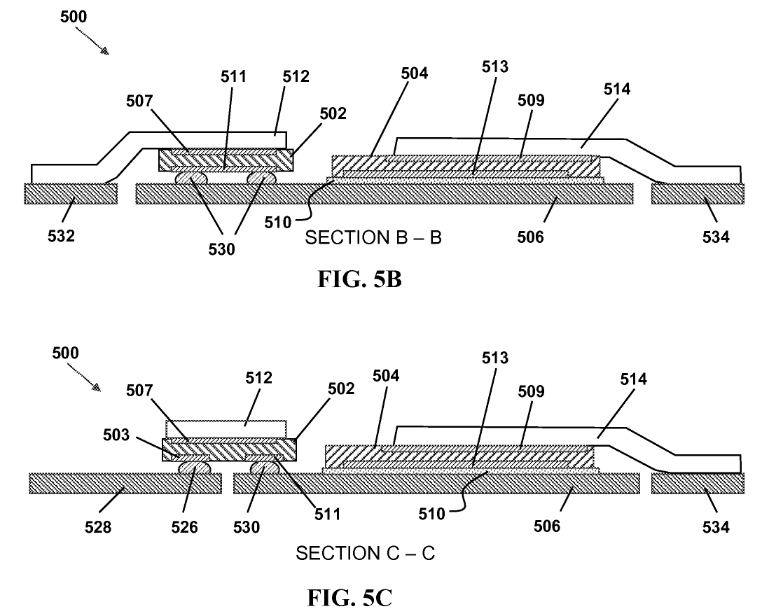

FIG. 5A is a top view of a power converter circuit package 500 having plate bonded co-packaged high-side and low-side NMOSFETs including a “flip chip” mounted high-side standard (bottom drain) VDMOSFET with plate bonded gate. As shown in FIG. 5A, a “flipped” high-side standard VDMOSFET 502 and a low-side standard VDMOSFET 504 may be packaged on a common die pad 506. As seen in FIGS. 5B-5C the high-side VDMOSFET 502 may be mounted in a “flipped” configuration with a gate pad 503 and a source pad 511 on a side facing the common die pad 506. In the following text, high-side VDMOSFET refers to high-side standard (bottom drain) VDMOSFET in the “flipped” configuration. The source pad 511 is in electrical contact with the common die pad 506 through “flip chip” solder balls 530. In this embodiment, a gate pad 503 of the high-side VDMOSFET 502 may be electrically connected to a gate lead 528, which is located underneath the high-side VDMOSFET 502 adjacent the common die pad 506. Electrical connection between the gate pad 503 and the gate lead 528 may be implemented, e.g., through one or more chip scale package (CSP)/“flip chip” solder balls 526, which may be placed between the high-side VDMOSFET 502 and the gate lead 528 in locations aligned with the gate pad 503 to provide electrical contact.

In the “flipped” configuration, a drain pad 507 of the high-side VDMOSFET 502 may be located on a side facing away from the common die pad 506. The drain pad 507 may be electrically connected to a drain lead 532 through a “flip chip” bond plate 512. The “flip chip” bond plate 512 may include a plurality of drain dimples 515 and anchor holes 517. The drain dimples 515 may be positioned and stamped or punched on the “flip chip” bond plate 512 so as to align with a drain pad of the high-side VDMOSFET 502 during solder reflow. Soft solder may be disposed in the drain dimples 515 and allowed to flow through holes (not shown) in the drain dimples 515 to the drain pad 507 on the high-side VDMOSFET 502 to form electrical interconnections between the drain pad 507 and the drain lead 532. CSP/“flip chip” solder balls 530 may be positioned between the high-side VDMOSFET 502 and the common die pad 506 for source electrical interconnection. CPS/“flip chip” solder balls 526 and 530 can be copper pillar or solder balls with a diameter of about 100 μm.

Similarly to the low-side standard VDMOSFET 304 of FIG. 4, a source pad 509 of the standard VDMOSFET 504 may be electrically connected to a source lead 534 through a low-side source bond plate 514. The low-side source bond plate 514 may include a plurality of source dimples 516 and anchor holes 518. The source dimples 516 may be positioned and stamped or punched on the second bond plate 514 so as to align with the source pad 509 during solder reflow. A gate pad 505 of the low-side standard VDMOSFET 504 may be electrically connected to a gate lead 524 through a gate plate 522. The gate plate 522 may include a dimple 520, which is positioned and stamped or punched on the gate plate 522 so as to align with the gate pad 505 during solder reflow. Soft solder may be disposed in the source dimples 516 and gate dimple 520 and allowed to flow through holes (not shown) in the source dimples 516 to the source pad 509 to form electrical interconnections between the sources pad 509 and the source lead 534. A drain pad 513 of the low-side standard VDMOSFET 504 faces and is in electrical contact with the common die pad 506. The low-side standard VDMOSFET 504 may be electrically attached to the common die pad 506 by a conductive epoxy layer 510.

FIG. 5B is a cross-sectional view of a power converter circuit package 500 with plate bonded co-packaged high-side and low-side MOSFETs having a high-side “flipped” VDMOSFET 502 of FIG. 5A taken along line B-B. As in FIG. 5A, high-side VDMOSFET 502 is mounted as a flip-chip so that the source is facing the common die pad 506. As shown in FIG. 5B, the CSP/flip chip solder balls 530 are positioned between the high-side VDMOSFET 502 and the common die pad 506 for electrical interconnection between the source pad 511 of the high-side VDMOSFET 502 and the common die pad 506. FIG. 5C is a cross-sectional view of a power converter circuit package 500 with plate bonded co-packaged high-side and low-side NMOSFETs having a high-side “flipped” VDMOSFET 502 of FIG. 5A taken along line C-C. As shown in FIG. 5C, the CSP/flip chip solder balls 530 may be positioned between the high-side VDMOSFET 502 and the common die pad 506 for electrical interconnection between the source pad 511 and the common die pad 506, while the CPS/flip chip solder ball 526 may be positioned between a gate lead 528 and the high-side VDMOSFET 502 and aligned with the gate pad 503 of the high-side VDMOSFET 502 for electrical interconnection between the gate pad 503 and the gate lead 528.

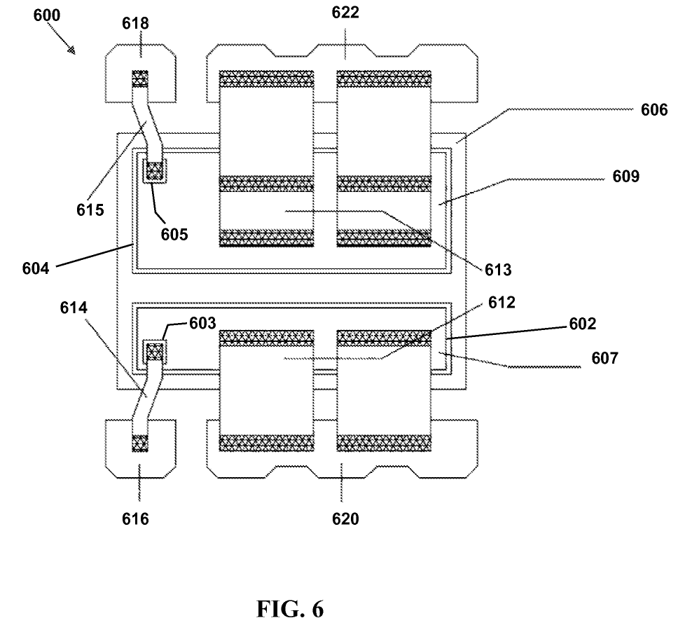

FIG. 6 is a top view schematic diagram illustrating a power converter circuit package 600 having co-packaged high-side and low-side NMOSFETs with aluminum power ribbon interconnections. As shown in FIG. 6, a bottom source high-side LDMOSFET 602 and a low-side standard VDMOSFET 604 are packaged on a common die pad 606. A drain pad 607 of the bottom source high-side LDMOSFET 602 may be electrically connected to a drain lead 620 using one or more aluminum power ribbons 612. Similarly, a source pad 609 of the low-side standard VDMOSFET 604 may be electrically connected to a source lead 622 through one or more aluminum power ribbons 613. Gate pads 603, 605 of the high-side LDMOSFET 602 and low-side standard VDMOSFET 604 respectively may be electrically connected to respective gate leads 616 and 618 through aluminum wires 614 and 615 respectively. The aluminum ribbons 612, 613 and aluminum wires 614, 615 may be bonded to the pads and the leads, e.g. using ultrasound heating. Alternatively, the gate pads 603, 605 may be electrically connected to respective gate leads 616, 618 through bond wires, bond plates or aluminum power ribbons (not shown).

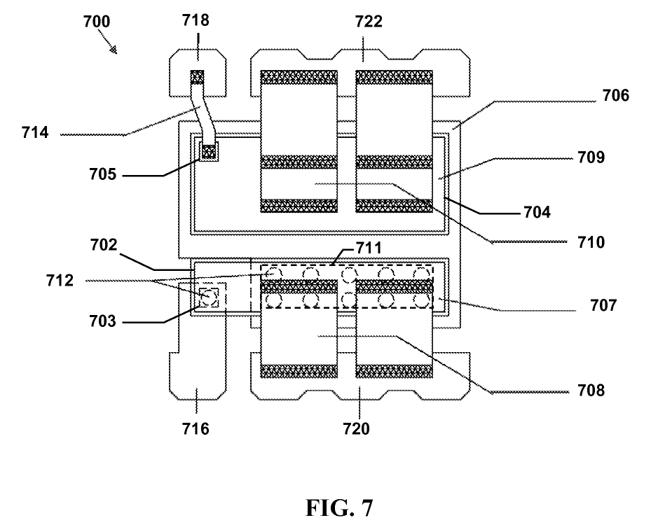

FIG. 7 is a top view schematic diagram illustrating a power converter circuit package 700 having a high-side standard VDMOSFET in a “flipped” or “flip chip” configuration co-packaged with a low-side standard VDMOSFET with aluminum power ribbon interconnections. As shown in FIG. 7, a “flipped” high-side VDMOSFET 702 and a conventionally-mounted low-side standard VDMOSFET 704 are packaged on a common die pad 706. A drain pad 707 of the high-side VDMOSFET 702 may be electrically connected to a drain lead 720 through aluminum power ribbon or clip 708. Solder balls 712 may be positioned underneath the high-side VDMOSFET 702 for electrical interconnections between a source pad 711 of the high-side VDMOSFET 702 and the common die pad 706 and between a gate pad 703 of the high-side VDMOSFET 702 and a gate lead 716.

A source pad 709 of the low-side VDMOSFET 704 may be electrically connected to a source lead 722 through an aluminum power ribbon or clip 710. A gate pad 705 of the low-side VDMOSFET 704 may be electrically connected to gate lead 718 through an aluminum wire or clip 714. Alternatively, the gate pads 703, 705 may be electrically connected to respective gate leads 716, 718 through bond wires, bond plates or aluminum power ribbons (not shown).

The aluminum ribbons and aluminum wires may be bonded to pads and leads, e.g. using ultrasound heating.

Embodiments of the present invention allow high-side and low-side NMOSFETS to be packaged in less space than in prior art packaging configurations. Smaller packaging space for the NMOSFETS allows power-converter circuit packages and the devices with which they are associated to be made smaller and less expensive. Furthermore, use of a common die pad may greatly reduce or even eliminate parasitic inductances associated with conventional packaging of high-side and low-side NMOSFETS.

While the above is a complete description of the preferred embodiment of the present invention, it is possible to use various alternatives, modifications and equivalents. For example the high-side and low-side NMOSFETs are assigned specific transistor types, e.g., LDMOSFET, VDMOSFET, which are the preferred embodiments but are not meant to limit embodiments of the invention to those transistor types. In principle, any type of vertical NMOSFET may be used, so long as the drain and the source are in the same positions (top or bottom) as detailed in the description of the embodiments.

Furthermore, although the above describes an embodiment of the present invention as applied to power conversion circuits, embodiments of the present invention are not limited solely to such applications. Embodiments of the invention may be applied to any situation in which two vertical NMOSFETs are so arranged that the drain of one NMOSFET is in electrical contact with the source of the other.

Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A circuit package assembly, comprising:
a common die pad;
a first vertical n-channel metal oxide semiconductor field effect transistor (NMOSFET) having an electrical contact to a source thereof on a side facing a surface of the common die pad and in electrical contact therewith;
a second vertical n-channel metal oxide semiconductor field effect transistor (NMOSFET) having an electrical contact to a drain thereof on a side facing the common die pad and in electrical contact therewith.

2. The circuit package assembly of claim 1 wherein the first NMOSFET is a high-side NMOSFET and wherein the second NMOSFET is a low-side NMOSFET

3. The circuit package assembly of claim 2 wherein the high-side NMOSFET comprises a bottom source n-channel lateral double diffused MOSFET (LDMOSFET) and wherein the low-side NMOSFET comprises a bottom drain n-channel vertical double diffused MOSFET (VDMOSFET).

4. The circuit package assembly of claim 2, wherein a gate pad and a drain pad of the high-side NMOSFET are located on a side of the high-side NMOSFET facing away from the common die pad, and wherein the gate pad and drain pad are electrically connected to gate and drain leads respectively.

5. The circuit package assembly of claim 1, wherein a gate pad and a source pad of the second NMOSFET are electrically connected to gate and source leads respectively through a plurality of bond wires.

6. The circuit package assembly of claim 2, wherein a drain pad of the high-side NMOSFET and a source pad of the low-side NMOSFET are located on a side of the high-side NMOSFET and the low-side NMOSFET respectively facing away from the common die pad, and wherein the drain pad and source pad are electrically connected to drain and source leads through first and second bond plates respectively.

7. The circuit package assembly of claim 6, wherein the first bond plate includes a first plurality of dimples formed thereon coupling the drain lead to a drain pad on the high-side NMOSFET, the dimples being positioned for contact with the drain pad and wherein the second bond plate includes a second plurality of dimples formed thereon coupling the source lead to a source pad on the low-side NMOSFET, the dimples being positioned for contact with the source pad.

8. The circuit package assembly of claim 7, wherein the first and second pluralities of dimples are soldered respectively to the drain pad and the source pad.

9. The circuit package assembly of claim 8, wherein a gate pad of the high-side NMOSFET and a gate pad of the low-side NMOSFET are electrically connected to gate leads through bond wires or wherein the gate pad of the high-side NMOSFET and the gate pad of the low-side NMOSFET are electrically connected to gate leads through high-side and low-side gate bond plates.

10. The circuit package assembly of claim 10, wherein the high-side gate bond plate includes a dimple formed thereon, the dimple being positioned for contact with the gate pad on the high-side NMOSFET and/or wherein the low-side gate bond plate includes a dimple formed thereon coupling the gate lead to a gate pad on the low-side NMOSFET, the dimple being positioned for contact with the gate pad on the low-side NMOSFET.

11. The circuit package assembly of claim 10, wherein the dimple is soldered to the gate pad on the low-side NMOSFET.

12. The circuit package assembly of claim 2 wherein a drain pad of the high-side NMOSFET located on a side facing away from the common die pad and a source pad of the low-side NMOSFET located on a side facing away from the common die pad are electrically connected to drain and source leads respectively through one or more aluminum power ribbons.

13. The circuit package assembly of claim 12, wherein gate pads of the high-side NMOSFET and the low-side NMOSFET are electrically connected to gate leads through wires, or wherein gate pads of the high-side NMOSFET and the low-side NMOSFET are electrically connected to gate leads through bond plates or power ribbons.

14. The circuit package assembly of claim 2, wherein the high-side NMOSFET is a bottom drain NMOSFET having one or more drain pads on a bottom side and a gate pad and one or more source pads at a top side and is mounted to the common die pad in a “flipped” configuration as a “flip chip” with the top side proximate to and facing the common die pad, whereby the gate pad and the one or more source pads are proximate to and facing the common die pad.

15. The circuit package assembly of claim 14, wherein the drain pads of the high-side “flipped” NMOSFET and one or more source pads of the low-side NMOSFET are electrically connected to corresponding drain and source leads through corresponding high-side and low-side bond plates.

16. The circuit package assembly of claim 12, wherein the “flip chip” bond plate includes a plurality of dimples formed thereon adapted to couple the drain lead to the one or more drain pads on the high-side “flipped” NMOSFET, the dimples being positioned for contact with the drain pads.

17. The circuit package assembly of claim 16, wherein the high-side “flipped” NMOSFET further includes source and gate electrical connections formed using one or more solder balls.

18. The circuit package assembly of claim 17, wherein the low-side source bond plates include a bond plate having a plurality of dimples formed thereon, the bond plate being configured to couple the source lead to source pads on the low-side NMOSFET, the dimples being positioned for contact with the one or more source pads.

19. The circuit package assembly of claim 18, wherein the plurality of dimples on the low-side source bond plate are soldered to the one or more source pads on the low-side NMOSFET and/or wherein a gate of the low-side NMOSFET is electrically connected to a gate lead through a low-side gate bond plate having a dimple formed thereon coupling the gate lead to a corresponding gate pad on the low-side NMOSFET, the dimples being positioned for contact with the gate pad.

20. The circuit package assembly of claim 19, wherein the dimple on the low-side gate bond plate is soldered to the gate pad.

21. The circuit package assembly of claim 14, wherein sources of the low-side NMOSFET are electrically connected to source leads through one or more conductive power ribbons or clips and/or wherein a gate of the low-side NMOSFET is electrically connected to a gate lead through a conductive wire or clip.

22. The circuit package assembly of claim 21, wherein a drain of the high-side “flipped” NMOSFET is electrically connected to one or more drain leads through a conductive power ribbon or a conductive clip and/or wherein a gate of the high-side “flipped” NMOSFET is electrically connected to a gate lead through a solder ball.

23. A circuit package assembly, comprising:
a common die pad;
a high-side n-channel metal oxide semiconductor field effect transistor (high-side NMOSFET) having an electrical contact to a source thereof on a side facing a surface of the common die pad and in electrical contact therewith, wherein the high-side NMOSFET comprises a bottom source n-channel lateral double diffused MOSFET (LDMOSFET);
a low-side standard n-channel metal oxide semiconductor field effect transistor (low-side NMOSFET) having an electrical contact to a drain thereof on a side facing the common die pad and in electrical contact therewith, wherein the low-side NMOSFET is a vertical double diffused MOSFET (VDMOSFET).

24. A circuit package assembly, comprising:
a common die pad;
a high-side n-channel metal oxide semiconductor field effect transistor (high-side NMOSFET) having an electrical contact to a source thereof on a side facing a surface of the common die pad and in electrical contact therewith, wherein the high-side NMOSFET is mounted to the common die pad in a “flipped” configuration as a “flip chip”;
a low-side standard n-channel metal oxide semiconductor field effect transistor (low-side NMOSFET) having an electrical contact to a drain thereof on a side facing the common die pad and in electrical contact therewith, wherein the low-side NMOSFET is a vertical double diffused MOSFET (VDMOSFET).

25. A circuit package assembly, comprising:
a common die pad;
a high-side n-channel metal oxide semiconductor field effect transistor (high-side NMOSFET) having an electrical contact to a source thereof on a side facing a surface of the common die pad and in electrical contact therewith;
a low-side standard n-channel metal oxide semiconductor field effect transistor (low-side NMOSFET) having an electrical contact to a drain thereof on a side facing the common die pad and in electrical contact therewith; and
a MOSFET driver integrated circuit (IC) having a high-side gate driver output coupled to a gate of the high-side NMOSFET and a low side gate driver coupled to a gate of the low-side NMOSFET.
